(19) United States
(12) Patent Application Publication
(10) Pub. No.: US 2010/0321017 A1
(43) Pub. Date: Dec. 23, 2010

(54) ULTRAHIGH TIME RESOLUTION MAGNETIC RESONANCE

(76) Inventors: Alexander Pines, Berkeley, CA (US); Elad Harel, Oakland, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 12/675,566

(22) PCT Filed: Aug. 29, 2008
(86) PCT No.: PCT/US08/74904

§ 371 Date: Aug. 26, 2010

Related U.S. Application Data
(60) Provisional application No. 60/969,409, filed on Aug. 31, 2007.
(60) Provisional application No. 61/043,375, filed on Apr. 8, 2008.

(51) Int. Cl. G01R 33/48

(52) U.S. Cl. 324/309

(57) ABSTRACT

Ultrahigh time resolution magnetic resonance is achieved in a flow-through device such as a microfluidic chip by imaging along the flow dimension. Position within the one-dimensional image may be related to time by the flow velocity. Thus, a time resolution corresponding to the one-dimensional image resolution is obtainable.

### RELATED APPLICATIONS

This application claims the benefit of U.S. Provisional Application Nos. 60/969,409, filed Aug. 31, 2007, and 61/043,375, filed Apr. 8, 2008, both of which are incorporated herein by reference in their entirety.

### STATEMENT REGARDING FEDERALLY SPONSORED R&D

The invention described and claimed herein was made in part utilizing funds supplied by the U.S. Department of Energy under Contract No. DE-ACO2-05CH11231. The government has certain rights in this invention.

### BACKGROUND

1. Field of the Invention

The present inventions relates to the field of nuclear magnetic resonance and magnetic resonance imaging.

2. Description of the Related Art

Microfluidics, which enables the control of fluid flow on a very small scale, holds great promise for advancing research in a diversity of fields, ranging from ligand binding for drug development to synthetic chemistry. It is also being used to perform fundamental studies of chemical, physical, and biological processes. Much effort has been devoted to understanding the fluid flow inside microfluidic devices since this plays a key role in their function. While optical methods are well-suited for fluid tracing they suffer from serious drawbacks such as a lack of chemically specificity and the need for optically transparent devices. Without the addition of optically active chromophores or flurophores, different fluids cannot be tracked. With tracers there is always the risk of altering the hydrodynamics of the flow itself. For the monitoring of chemical reactions tracers are, in general, not useful.

To date only a few optical techniques have been designed to directly measure a spectrum from a single point on the micro fluidic device. These methods suffer from poor sensitivity due to the very short optical path length through the micro fluidic channel. Furthermore, they do not provide any type of flow information or imaging modality. Nuclear magnetic resonance imaging, on the other hand, is routinely capable of providing simultaneous spatial and spectral information through a technique called chemical-shift imaging. However, doing so on a microfluidic chip is a formidable task for several reasons. First, the NMR signal is very weak, requiring 10¹⁵-10¹⁸ spins, on average, for an inductive detection. On channels with cross sectional area below 10⁻⁸ m², sensitivity becomes a significant challenge, especially for imaging.

Secondly, local variations in the magnetic field due to susceptibility gradients at the fluid, glass, and air interfaces effectively destroy the homogeneity of a high-field magnet, precluding an identification based on the chemical shift. While there may be ways to fabricate chips and coils to overcome this magnetic susceptibility problem they are generally incompatible with well-established protocols for chip fabrication already in place. More problematic is that RF excitation and detection must occur over the volume of the entire chip, while only a fraction is occupied by the fluid that gives rise to the NMR signal, resulting in a very low filling factor. While NMR surface coils can be used to increase sensitivity they are, in general, limited to examining only a single or, at most, a very few number of points on the chip. Additionally, their large fingerprint (>1 mm) precludes examining regions of congested channels. The specialized hardware needed to control multiple coils is restrictive. Finally, imaging under rapid flow (>100 mm/min) is extremely challenging using any type of echo based pulse sequences unless very dedicated hardware is constructed that matches the geometry of the microfluidic chip in question. Furthermore, direct imaging methods of this type, while powerful, require significant signal averaging even at tens of molar concentrations and are therefore better suited for fluid dynamic studies than for chemical or biological problems.

Additional complications with chemical-shift imaging of a flow-through system such as a microfluidic chip arise due to the Nyquist condition, which sets a lower bound on the time evolution needed to achieve a given frequency resolution. The time resolution of fluid flow is determined by the residence time of the spins inside the detection region. A high time resolution (i.e., low residence time) results in low spectral resolution.

For example, resolving two resonances that are 100 Hz apart would require a minimum of approximately 10 ms of chemical shift evolution, not including the time needed to actually execute the pulse sequence and, in the case of rapid imaging, traverse the entire k-space trajectory. The state of the art in MRI for such fast imaging (e.g., echo planar imaging (EPI) and steady state free precession (SSFP)) can achieve no better than around 20-50 ms time resolution at optimal conditions. On a microfluidic chip it is unlikely that the sensitivity of direct detection and the extremely fast flow rates of the fluids would even allow such imaging sequences which rely on high sensitivity, high homogeneity, and specialized hardware. Additionally, these sequences do not allow for chemical-shift imaging.

Thus, there is an unmet need for methods of obtaining ultrahigh time resolution magnetic resonance of flow-through systems such as microfluidic chips.

### SUMMARY OF THE INVENTION

One embodiment disclosed herein includes a magnetic resonance detection method that includes applying a static magnetic field to a flow-through system comprising a fluid, applying a first radiofrequency pulse to the fluid located within the flow-through system to excite nuclear spins in the fluid, transporting the fluid from the flow-through system into a detection coil, and performing one-dimensional nuclear magnetic resonance imaging of the fluid within the detection coil.

Another embodiment disclosed herein includes a method of imaging fluid within a microfluidic chip including: a) applying a first radiofrequency excitation pulse and a magnetic field gradient to fluid within the chip; b) allowing the fluid to flow through a detection coil located remotely from the chip; c) applying a second radiofrequency excitation pulse with the detection coil to the fluid within the detection coil; d) applying a magnetic field gradient to the fluid within the detection coil; e) measuring a free induction decay curve with the detection coil; f) repeating steps c) through e) until all fluid within the chip at the time of the application of the first excitation pulse has flowed through the detector; g) repeating steps a) through f) for a variety of magnetic field gradients applied to the chip and a variety of magnetic field gradients applied to the fluid within the detection coil; h) constructing a kt-space from the plurality of free induction decay curves; and i) converting the kt-space to a real image of spin density within the microfluidic chip for desired time-of-flight of the fluid flowing from the chip to the detector.

Another embodiment disclosed herein includes an ultrafast nuclear magnetic resonance apparatus that has a plurality of coils and corresponding drivers configured to apply magnetic field gradients in three dimensions and a detection coil and corresponding driver configured to apply radiofrequency excitation pulses and detect nuclear resonance free induction decay, wherein the detection coil is positioned within the plurality of gradient generating coils such that magnetic field gradients can be generated within the detection coil.

### BRIEF DESCRIPTION OF THE DRAWINGS

FIG. 1 is a schematic depicting gradient coils within a magnet core for imaging of a microfluidic chip.

FIG. 2A is a schematic depicting a microfluidic chip and detection coil and the gradients applied to obtain time-resolved imaging of fluid within the microfluidic chip.

FIG. 2B is a schematic illustrating a series of voxels within the microfluidic chip and the corresponding one-dimensional image obtained with the detection coil.

FIG. 2C is a schematic depicting a series of voxels corresponding to different times-of-flight within the microfluidic ship.

FIG. 3A is a graph in depicting flow of a fluid exiting a microfluidic chip.

FIG. 3B is a graph depicting a free induction decay curve for fluid within a detection coil.

FIG. 3C is a graph depicting the one-dimensional profile of fluid within the detection coil.

FIG. 4 is a flowchart illustrating one method for ultrahigh time magnetic resonance detection.

FIG. 5 depicts timelines illustrating one pulse sequence for ultrahigh time magnetic resonance detection.

FIG. 6 is a schematic illustrating two microfluidic chips usable in microfluidic chromatography.

FIG. 7 is schematic illustrating a weir in a microfluidic chip channel.

FIG. 8 is a perspective view of a microfluidic top plate and bottom plate illustrating one weir construction technique.

FIG. 9A is a schematic depicting fluid flow through a porous material.

FIG. 9B is a schematic illustrating fluid distributed by velocity in a detection coil and the resulting one-dimensional image.

FIG. 10 is a schematic illustrating an apparatus for performing ultrahigh time resolution magnetic resonance.

FIG. 11 is a series of photographs depicting separate spin density for benzene and acetonitrile within a microfluidic chip for successive periods of time-of-flight.

FIG. 12A is a series of partial photographs depicting separate spin density for benzene and acetonitrile within a microfluidic chip for successive periods of time-of-flight.

FIG. 12B is close-up view of a pair of the partial images.

FIG. 13 is a traditional high-resolution magnetic resonance image of a microfluidic chip under stationary flow conditions.

FIG. 14 is a series of photographs depicting spin density of successive periods of time-of-flight and velocity portioning of fluid flowing through a capillary.

### DETAILED DESCRIPTION OF THE CERTAIN EMBODIMENTS

Some embodiments provide methods for ultrahigh time resolution magnetic resonance detection by transforming the time dimension into a space dimension. Such techniques may be used to obtain fast successive magnetic resonance images that are both time-resolved as well as spectrally-resolved. In other words, images of a system of interest can be obtained that show fast time evolution selectively for various chemical species in the system.

In one embodiment, ultrahigh time resolution magnetic resonance of fluid within a flow-through system is obtained using remote detection. In one embodiment, magnetic resonance imaging is conducted along the flow dimension. In such an embodiment, one or more fluids that are excited when they are in the flow-through system are detected when they flow through a detection coil after exiting the flow-through system. One-dimensional magnetic resonance imaging of the fluid in the detection coil may then be performed. The spatial dimension along the detection coil may be related to successive periods of time due to the fact that space and time are related by the flow velocity. Thus, the one-dimensional detection coordinate may be partitioned, with each partition corresponding to a partition of time. The Nyquist condition is thereby significantly relaxed, allowing the various components in the fluid to be resolved using chemical shift information. This information may be used to provide nuclear magnetic resonance (NMR) spectroscopy as a function of time-of-flight through the flow-through system and/or magnetic resonance images (MRI) of each fluid component as a function of time-of-flight (i.e., chemical-shift imaging).

As used herein, “one-dimensional magnetic resonance imaging” refers to any technique that allows the generation of magnetic resonance data as a function of position along the detection dimension. The data may be in any suitable format including raw magnetic resonance signal, spectral information, or spin density and may be displayed, stored, and/or processed in a variety formats including a numerical array, a graph, or picture representation. The use of the term “image” does not necessarily mean the display of a picture representation.

As used herein, a “flow-through system” refers to any structure having channels or tubes through which fluid may flow from one or more inlets to one or more outlets. The fluid may include a liquid, gas, mixtures of liquids and/or gases, and solutions. In some embodiments, the flow-through system is a microfluidic device, such as a microfluidic chip in which channels for fluid flow have been created. Such chips may be used for a variety of applications including synthetic chemistry, biological assays, chromatography, as well as fundamental studies of flow processes. The ultrafast techniques described herein allow for imaging of such processes to reveal their chemically resolved dynamics. Furthermore, the ultrafast techniques allow the acquisition of time-resolved NMR spectra of fluid present at various locations across the microfluidic chip. Other microfluidic devices may also be analyzed using the techniques described herein, for example a device constructed of capillaries or a biological system (e.g., comprising vasculature).

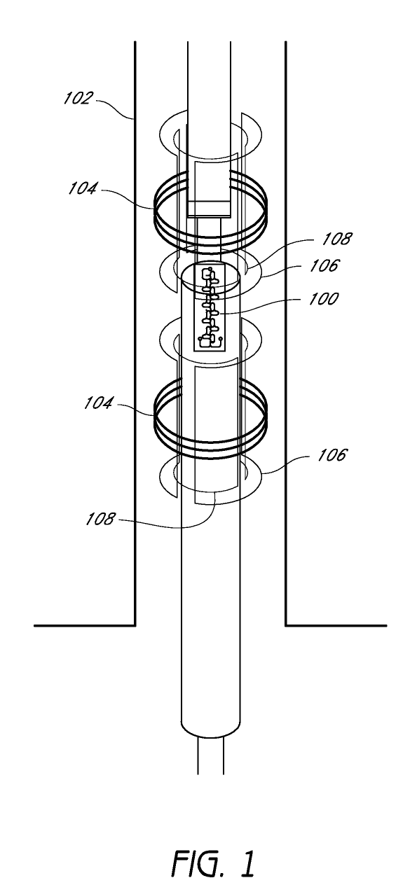

In some embodiments, spatial encoding for construction of images of chemical species within the flow-through system or for identification of a location of fluid within the flow-through system for which an NMR spectrum is obtained utilizes well known techniques for magnetic resonance imaging. FIG. 1 depicts one suitable imaging apparatus in which a microfluidic chip 100 is placed within the core 102 of a strong magnet that generates a static magnetic field. Any suitable magnet may be used including a permanent magnet, electromagnet, or superconducting magnet. In some embodiments, the magnet from a conventional NMR spectrometer or MRI device may be utilized. Magnetic field gradient coils may also be placed within the magnet core surrounding the microfluidic device. In various embodiments, depending on the desired dimension of imaging, magnetic field gradient coils may be used to provide gradients along x, y, and/or z dimensions (with the z dimension corresponding to the static magnetic field generated by the strong magnet 102). Any suitable coils may be used to generate gradients. For example, z-gradients may be generated using a pair of Maxwell coils 104 while x- and y-gradients may be generated by pairs of saddle coils, 106 and 108, respectively. For the typical two-dimensional pattern formed by microfluidic chip channels, chip encoding gradients need only be applied along the y- and z-axes with the face of the chip lying in the y,z plane. An additional gradient along the x-axis may be applied for purposes of imaging within the detection region as discussed in more detail below. Gradients along the x-axis can also be used to perform imaging in the third spatial dimension of the device, if so desired, to obtain a 3D image.

For remote detection, the output of the microfluidic device may be fed through a capillary surrounded by a detection coil. In some embodiments, the capillary and detection coil are also positioned within the gradient coils 104, 106, and 108. In one embodiment, the detection coil is aligned along the x-axis.

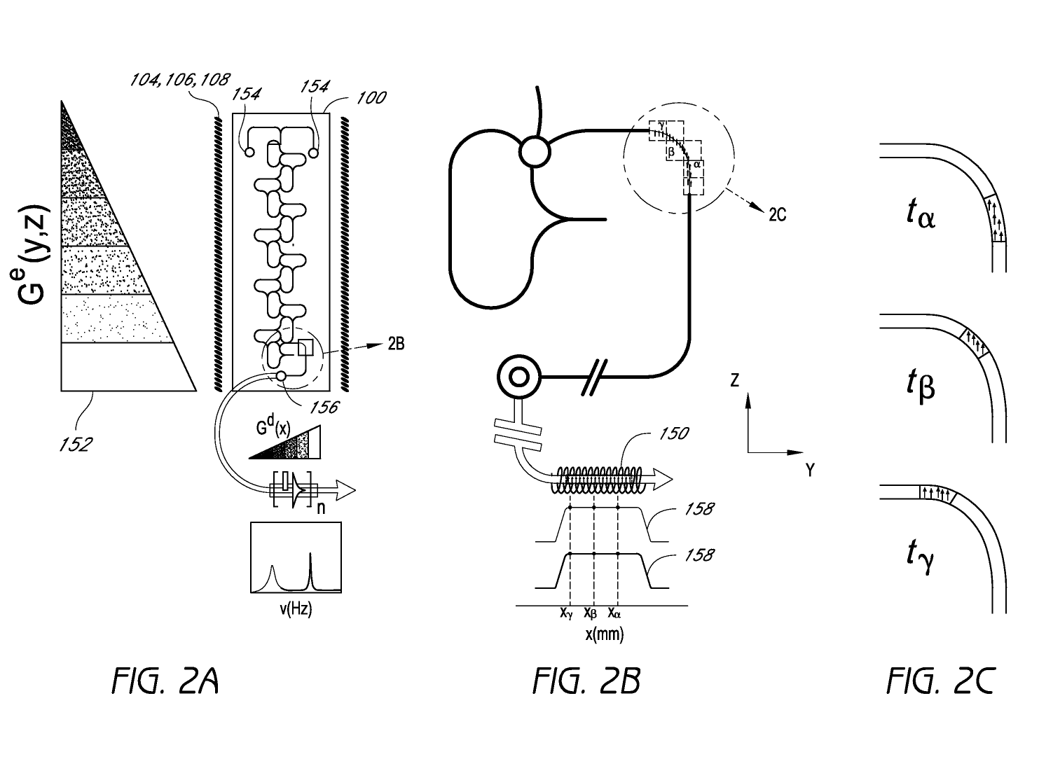

FIGS. 2A-2C depict one embodiment of a microfluidic chip 100 and illustrates the relationship between locations on the chip 100 and the time of fluid detection in the detection coil 150. As discussed above, the chip 100 is positioned within gradient coils 104, 106, and 108 (see FIG. 2A). For spatial encoding, encoding gradients 152 are applied along the y- and z-axes of the chip (i.e., along the face of the chip) after which the encoded spins are stored as described below. The chip 100 may include one or more fluid input ports 154 and a fluid output port 156. Fluid within the chip 100 is exposed to the encoding gradients 152 and then flow through the chip's channels until exiting at port 156, after which it flows through a capillary within the detection coil 150. In order to perform one-dimensional magnetic resonance imaging within the capillary, a gradient may be applied along the x-axis using the x-axis saddle coil 106. In order to resolve multiple chemical species within the fluid (for obtaining NMR spectra and/or chemical-shift imaging), phase encoding or spectrally selective excitation pulses may be used, as described in more detail below.

FIGS. 2B and 2C illustrate the relationship between the time-of-flight of fluid within the chip 100 and the one-dimensional image 158 formed within the detection coil 150. For example, spins located within the voxel a take a time t_{α} to flow to the detection coil 150. Similarly, spins in nearby voxels β and y travel to the detection coil in times t_{β} and t_{γ}, respectively (where t_{α}<t_{β}<t_{γ}). The fluid in the encoded voxel to arrive first in the detection coil 150 (α) is nearest to the outlet at the time of encoding. Each voxel may contain one or more fluid components. When all of the spins from voxels α, β, and γ are located within the detection coil 150, the spins from the respective voxels will be arranged at positions x_{α}, x_{β}, and x_{γ} within the coil 150 (where and x_{γ}<x_{β}<x_{α}). Thus, the partitioning of a one-dimensional image 158 along the detection coil 150 will indicate magnetic resonance information of fluid within the chip 100 as a function of time-of-flight of the fluid through the chip 100 utilizing the conversion tᵢ=xᵢ/v, where v is the flow velocity. For a small diameter capillary within the detection coil 150, the flow velocity is well-defined along the flow direction because it is highly laminar with minimal dispersion. As described in more detail below, phase encoding or spectrally selective pulses may be used to perform the one-dimensional imaging.

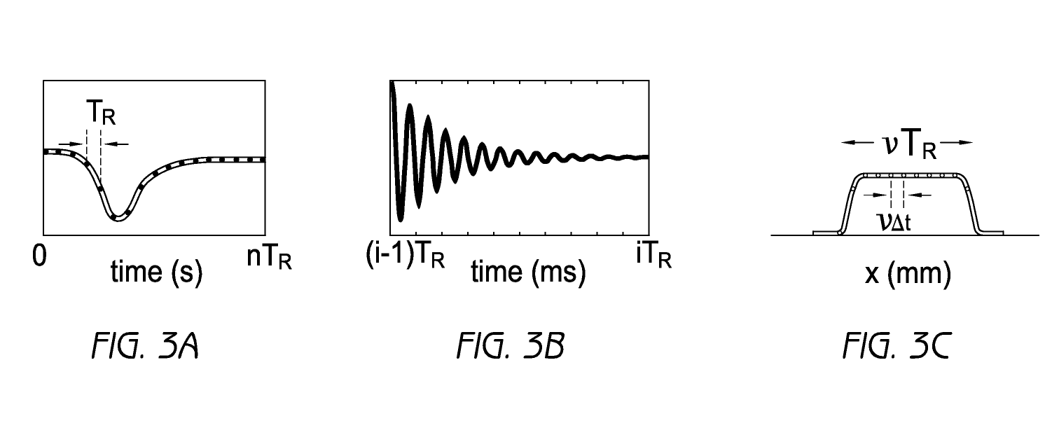

The entire range of fluid time-of-flight from the input ports 154 to the output port 156 may be probed by applying successive one-dimensional imaging techniques to the fluid within the detection coil 150. FIGS. 3A-3C illustrates this stroboscopic technique. FIG. 3A depicts the flow of a chemical species within the fluid exiting the chip 100 as a function of time over the course of the entire time-of-flight (nT_{R}) of fluid from the input ports 154 to the output port 156. The entire time-of-flight (nT_{R}) may be partitioned into n time periods, T_{R}, where each time period represents the time it takes the fluid to flow through the detection capillary (i.e., the residence time within the detection coil). At the start of each successive time period T_{R}, the spins in the fluid within the detection coil may be excited and the resulting free-induction decay measured for the duration of the residence time T_{R}, as illustrated in FIG. 3B. The effective T₂* relaxation is dominated by the residence time T_{R}. One-dimensional magnetic resonance imaging of the fluid within the detection coil at the time of excitation may be obtained from one or more free-induction decay curves, as illustrated in FIG. 3C, utilizing the techniques described below or using any other suitable technique. The resulting data along the detection dimension may be partitioned into spatial units Δx, which correspond to a time resolution of Δt (=Δx/v). After each residence time period T_{R}, another excitation pulse is applied and free-induction decay curve obtained. Thus, the entire volume of fluid in the chip 100 may be probed with a time resolution of Δt.

In some embodiments, the fluid flow through the chip 100 and detector 150 is continuous. In other embodiments, the fluid flow may be momentarily stopped or slowed during detection, such as by using a fast response valve on the chip 100 itself or at a location near the outlet. In some embodiments, stopped flow can allow an increase by about 3-4 orders of magnitude in sensitivity by increasing filling factor and reducing the spectral line width. For example, in some embodiments, the spectral line width may be reduced from about 50 Hz in continuous flow operation to about 2-3 Hz in stopped flow operation. In addition, stopped flow conditions can allow the use of robust imaging sequences applied in the detector 150. For example, in one embodiment, three-dimensional echo planar imaging is conducted in less than about 200 ms with high spatial resolution.

In one stopped flow embodiment, the volume of fluid to be imaged (e.g. the volume within the channels of the chip) is matched to the volume within the detector region. In one such embodiment, the volume within the detector can be increased by using a thin-walled capillary. For example, while the diameter within the channels of the chip 100 may be 150 μm, a capillary within the detection region having in outer diameter of 360 μm and an inner diameter of 300 μm may be used. In one embodiment, the volume within the detector is increased by increasing the length of the detector 150.

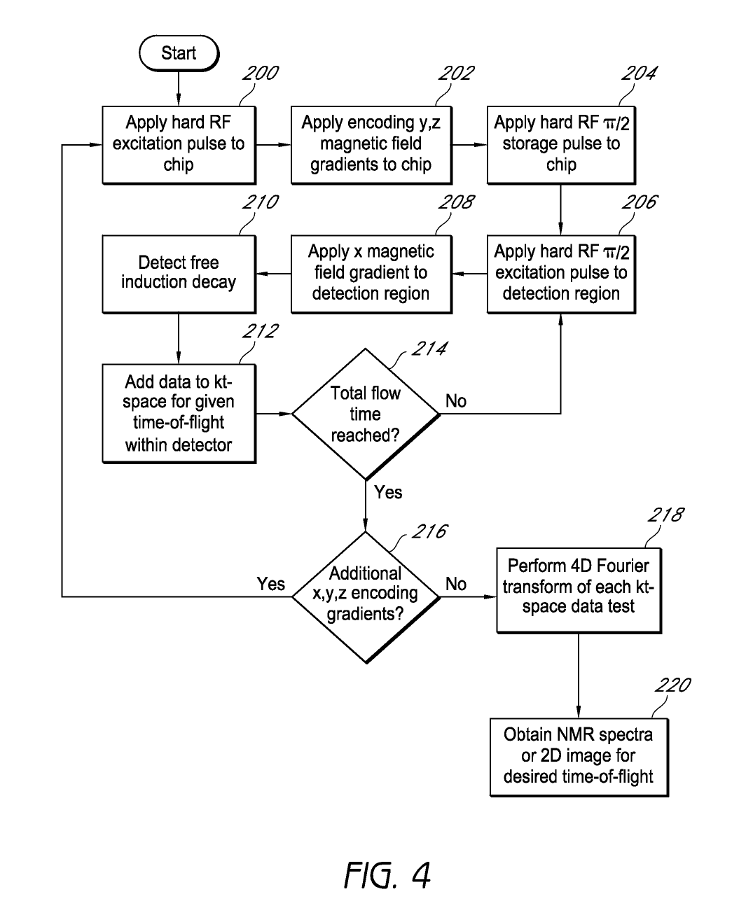

FIG. 4 is a flowchart illustrating one method for obtaining ultrahigh time resolution images and/or spectra of fluid within a flow-through system such as a microfluidic chip 100. The method illustrated in FIG. 4 provides time-resolved and spectrally resolved images of fluid flowing through the microfluidic chip 100. Thus, a series of time-of-flight images for each chemical species (or each chemical shift) can be obtained showing the flow of each species through the chip 100. At block 200, a hard 90 degree RF pulse is applied to the chip to excite all spins. Alternatively, a spatially selective pulse (e.g., a sinc pulse) may be applied in the presence of a pulsed gradient. Next, at block 202, an encoding magnetic field gradient in the y- and z-dimensions is applied to the chip 100. The spins are allowed to evolve in the presence of the encoding gradients. The entire encoding time may be relatively short (e.g., less than about 200 μs). In some embodiments, the gradient strengths are less than about 10 G/cm. After encoding, the evolution of the spin magnetization is stored along the longitudinal direction by application of a hard 90 degree RF pulse about the y-axis at block 204 such that the spins are subject only to T₁ relaxation, which is typically long enough to allow for remote detection after flowing through the chip 100. The phase of the storage pulse may be arrayed in steps of 90 degrees to allow for phase cycling, thereby removing the baseline signal due to unencoded spins as well as obtaining frequency discrimination. Those of skill in the art will appreciate other pulse sequences and gradients that may be applied for exciting, encoding, and storing nuclear spins in the flow-through system.

After application of the storage pulse, the detection sequence may be initiated. As described above with reference to FIG. 3, the detection sequence includes a series of pulses and acquisitions over the entire time-of-flight of fluid through the chip. Specifically, for phase encoded one-dimensional imaging, a hard 90 degree RF pulse is applied at block 206 by the detection coil 150 to the fluid in the detection region. This excitation pulse excites the stored spins back into the transverse plane, where they can freely precess. After excitation, a magnetic field gradient is applied in the x-direction at block 208 and the spins are allowed to evolve. Next, at block 210, the free induction decay (FID) of the excited spins is detected using the detection coil 150. The FID curve is sampled for the duration of the residence time of fluid in the detection region (T_{R}). At block 212, the raw data of the FID curve is added to a four-dimensional kt-space corresponding to the given time-of-flight of fluid within the detector (i.e., a given time-of-flight segment T_{R} from the entire flow time nT_{R}). This four-dimensional kt-space contains one dimension for the y-gradient, one dimension for the z-gradient, one dimension for the x-gradient, and the time dimension for the FID curve.

At decision block 214, a determination is made whether the entire volume of fluid in the chip 100 at the time of the chip excitation pulse has been measured. If not, the process of excitation pulse (block 206), application of x-dimension magnetic field gradient (block 208), FID detection (block 210), and population of kt-space (block 212) is repeated for another segment of fluid flowing through the detector. This process is repeated until the entire volume of fluid in the chip 100 has been detected (i.e., the sequence is repeated n times over the period nT_{R}). Once the entire time-of-flight period has been probed, the process continues to decision block 216.

At decision block 216, a determination is made whether additional unique combinations of x-, y-, and z-dimension gradients need to be encoded. If so, the process returns to block 200 for an additional excitation pulse to the chip 100 with subsequent application of y,z-dimension gradients (block 202), storage pulse (block 204), and detection sequence (blocks 206-214). It will be appreciated that in the phase encoding scheme for one-dimensional imaging, for each unique y,z-dimension gradient, the experiment will need to be repeated for a series of detection x-dimension gradients. Thus, the loop determined by block 216 will be repeated X×Y×Z times, where Y is number of different gradients applied in the y direction (i.e., the y-resolution), Z is the number of different gradients applied in the z direction (i.e., the z-resolution), and X is the number of different gradients applied in the x direction (i.e., the time resolution provided by the image resolution of the one-dimensional detector image). In addition, during each repetition, the loop determined by block 214 will be repeated n times in order to probe the entire volume of fluid excited in the chip 100 (i.e., it will be repeated during the time nT_{R}). Thus, X×Y×Z×n FID curves will be acquired. For experiments where the concentrations of the chemical species as a function of location within the chip 100 are not expected to change over time, the above sequence may be conducted under continuous flow operation. In other words, the chemicals provided at the input ports 154 can be continuously supplied during the sequence repetition.

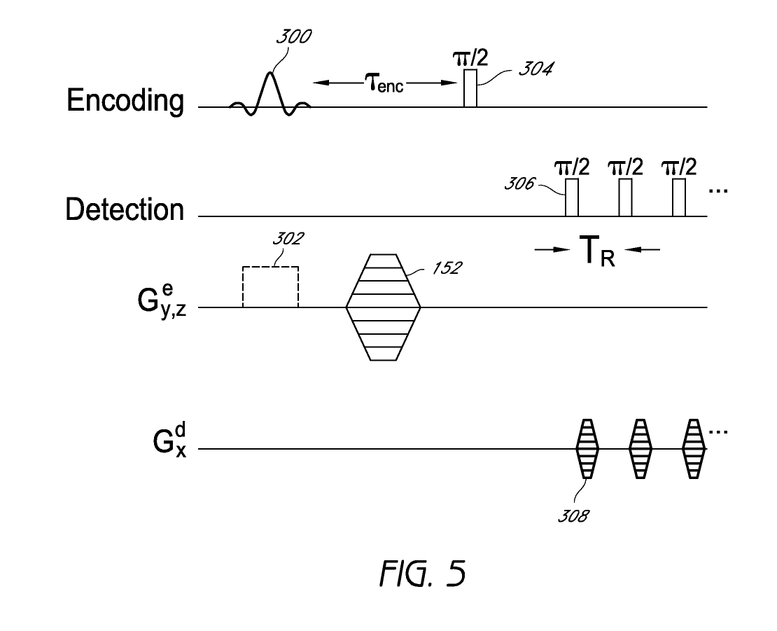

FIG. 5 depicts one possible embodiment of the pulse and gradient sequence referred to in the FIG. 4 flowchart. First, the excitation pulse 300 is applied to the chip 100 (either a hard 90 degree pulse or a sinc pulse in combination with a pulsed gradient 302). Next, a y,z dimension gradient 152 is applied to the chip 100 followed by a 90 degree hard storage pulse 304. Finally, in the detector region, a series of hard 90 degree excitation pulses 306 followed by application of an x-dimension gradient 308 is applied to obtain a series of FID curves spaced apart by the residence time T_{R}.

Returning to FIG. 4, after all combinations of x-, y-, and z-dimension gradients have been applied as determined at block 216, the data may be analyzed to construct time-resolved and spectrally-resolved images and/or to obtain time-resolved NMR spectra for each fluid location on the chip 100. At block 218, the constructed kt-space for each time-of-flight segment T_{R} is processed with a four-dimensional Fourier transform to generate a four-dimensional representation comprising 3 real space coordinates (corresponding to the x, y, and z dimensions) and one frequency coordinate corresponding to an NMR spectrum. Thus, an NMR spectrum for each combination of x, y, and z coordinates is obtained. At block 220, the desired magnetic resonance information is obtained for one or more desired times-of-flight. As discussed above, the position along the x-dimension (i.e., along the detector) corresponds to a specific time-of-flight within the relevant time-of-flight segment T_{R}. Thus, the information for the desired fluid time-of-flight may be obtained by selecting the data set corresponding to the time-of-flight segment T_{R} that contains the desired time-of-flight and then selecting the x coordinate that corresponds to that specific time-of-flight. The NMR spectrum for each y, z coordinate over the chip 100 for that time-of-flight may then be obtained directly from the Fourier-transformed data set. Alternatively, peaks within each NMR spectrum corresponding to a desired chemical shift (e.g., a desired species within the fluid) may be integrated to obtain spin density for each y, z coordinate over the chip 100 and a two-dimensional image may be generated for the given chemical species and time-of-flight. If the resolution of the one-dimensional image along the x-dimension allows partitioning into segments Δx, then the obtainable time resolution is Δt, where Δt=Δx/v.

Thus, real two-dimensional images for each chemical species with a time resolution of Δt can be obtained.

In one alternative embodiment, instead of applying a series of x-dimension magnetic field gradients for the one-dimensional imaging of the detector region, a spectrally-selective excitation pulse is applied at block 206 instead of the hard 90 degree pulse. Thus, each species in the fluid is excited separately and one-dimensional images for each species may be obtained using simple spin echo frequency encoding where a magnetic field gradient is applied along the x-dimension during readout. The detected magnetic resonance signal for each time-of-flight segment T_{R} and each species is added to a three-dimensional k-space comprising one dimension for the y-gradient, one dimension for the z-gradient, one dimension for the x-gradient. The three-dimensional k-space can then be processed by three-dimensional Fourier transformation to obtain a real space representation of spin density for the species as a function of x, y, and z. Partitioning along the x-dimension as above may be used to select a specific time-of-flight for which a 2D image of the chip 100 is then obtained.

This spectrally-selective approach provides higher time resolution but suffers some signal loss due to the fast flow of the fluid. For cases in which only a few chemical species need to be resolved, use of the spectrally-selective pulse may be advantageous. In cases, where more resolvable fluid components than time points are required, the phase encoding method described above is preferential. The phase encoding method is more time-intensive, but it also provides the entire spectrum “free of charge” so that each fluid component is simultaneously imaged. It will be appreciated that many other known techniques for one-dimensional imaging in the detector region may be used to construct the kt- or k-spaces which may then be processed to obtain time-resolved and spectrally-resolved images of the chip 100.

Although a particular apparatus design and set of RF pulses and magnetic field gradients have been described above, it will be appreciated that the general technique of obtaining ultrafast magnetic resonance information by remote one-dimensional imaging can be used in numerous other configurations. In the remote detection modality over two orders of magnitude increase in sensitivity over direct detection is achievable making this method ideally suited for the small analyte volumes present in microfluidic chips. Improvements in pulse sequences and the incorporation of more sophisticated microfluidic components could improve the experiment acquisition time by orders of magnitude. For example, collecting a series of images from only a small sub volume of the chip with sub-millisecond time resolution under the current sensitivity would take minutes instead of the few hours needed to collect an entire data set for the entire chip. This would allow zooming in on regions of interest with very high spatial resolution not currently achievable with direct detection MRI means. The addition of chemical identification by NMR makes this method extremely general.

Numerous applications utilizing the technique can be envisioned. One application includes the time-resolved and spectrally-resolved imaging of simple mixing of two or more fluids injected into a microfluidic chip. The imaging may be used to monitor the fluid dynamics of the various components through the chip. In another application, two or more substance may react upon mixing and the progress of the reaction may be monitored as the reagents and products flow through the chip.

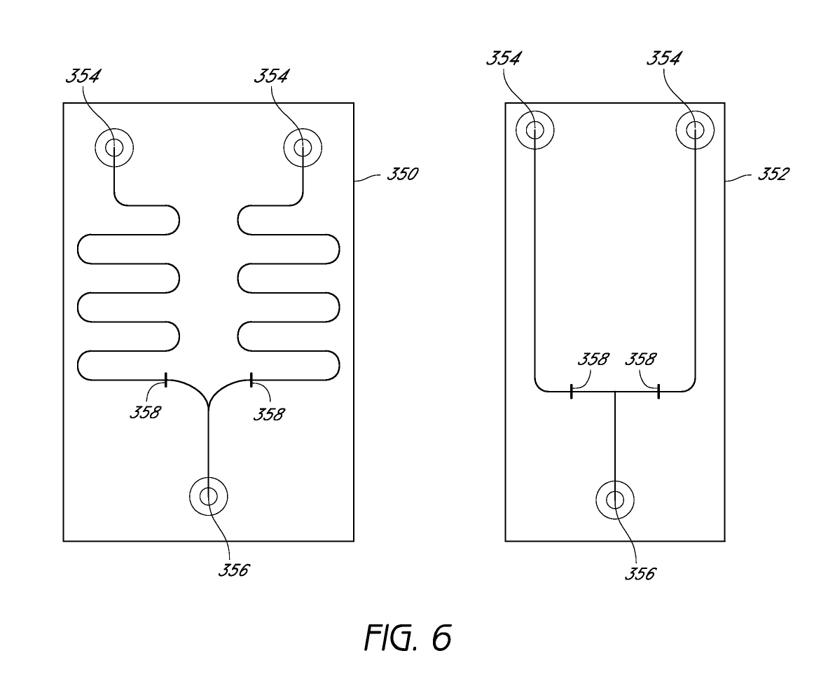

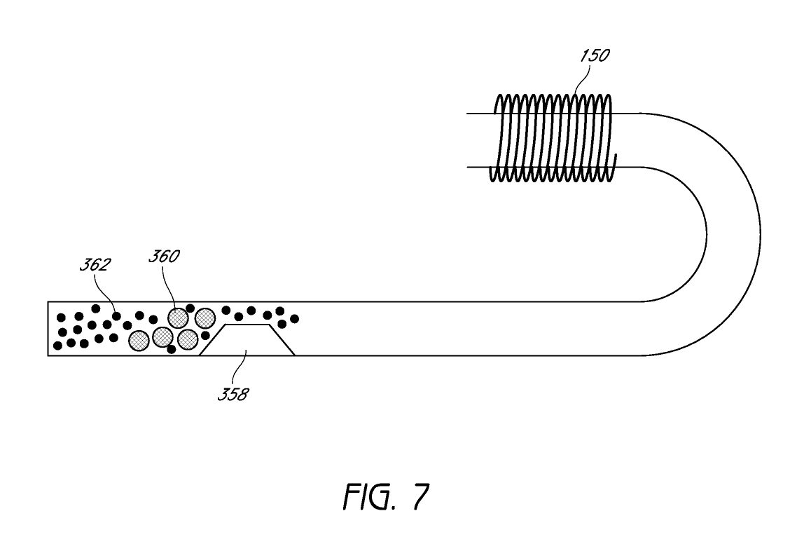

In still another application, a type of microfluidic chromatography can be performed. In one such embodiment, depicted in FIG. 6, a microfluidic chip 350 or 352 may be provided having one or more input ports 354 and an output port 356. The output port 356 may lead to a one-dimensional imaging detector as described above. One or more analytes of interest can be provided to the input ports 354. At a location close to the output port 356, weirs 358 may be fabricated which are capable of trapping small particles. FIG. 7 depicts a side view of a weir 358 with trapped particles 360. The particles 360 can be, for example, beads functionalized with a biological or chemical agent, such as proteins, ligands, or cells. In some embodiments, the beads 360 may be less than about 5 μm in diameter. When the analyte 362 flows through the beads 360, the interaction with the agents immobilized on the beads 360 will affect the time-of-flight of the analyte 362 through the beads 360 to the detector 150. This type of chromatography can be used for rapid assaying of analytes 362 with high sensitivity. In addition, using the techniques described above, images of the analyte 362 at different stages of flow and interaction with the stationary phase can be recorded with ultrahigh time resolution. For assays where interaction with the stationary phase is desired over a longer length, a serpentine pathway such as depicted in chip 350 can be used. In other embodiments, a shorter interaction pathway as depicted in chip 352 can be used. Chips 350 or 352 having multiple input ports 354 may be used to analyze multiple analytes simultaneously provided that they do not react. The analytes mix prior to exiting through the output port 356 and may be resolved through the techniques described above.

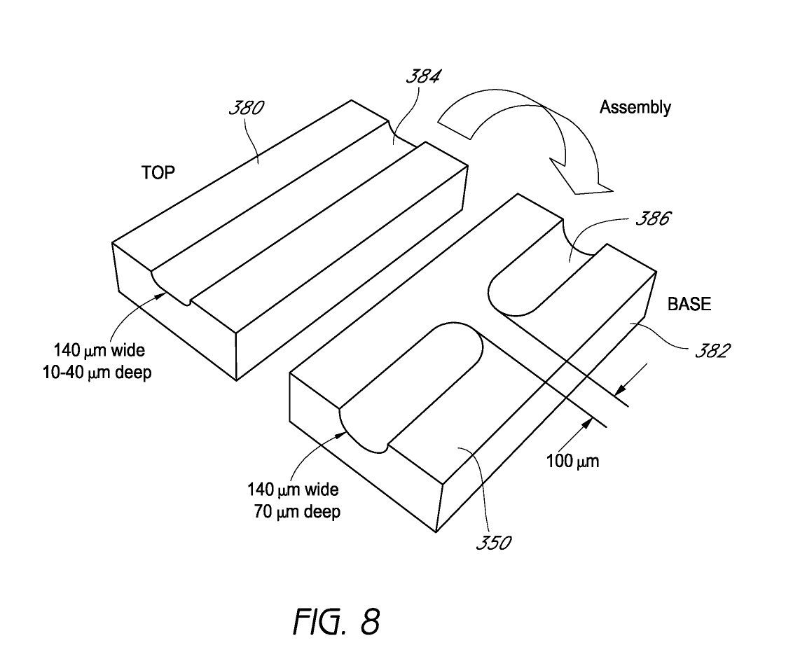

FIG. 8 is a perspective view showing the creation of weirs 358 in a microfluidic chip. The weirs 358 may be constructed by etching channels in both a top plate 380 and a bottom plate 382 of a microfluidic chip. The channel 384 in the top plate 380 may be etched all the way through in the area of the weir 350. In contrast, the channel 386 in the bottom plate 382 is selectively etched such that an unetched portion forms the weir 350. The top plate 380 may then be bonded to the bottom plate 382 to form a channel that is constricted by the weir 350. In some embodiments, the channel 384 in the top plate 380 is shallower than the channel 386 in the bottom plate 382. For example, the channel 384 in the top plate 380 may be from about 10 to about 40 μm deep while the channel 386 in the bottom plate 382 may be about 70 μm deep. Thus, a weir 350 of about 70 μm in height is created. In one embodiment, the unetched portion of the channel 386 in the bottom plate 382 is about 100 μm wide. Those of skill in the art will appreciate other methods for forming weirs in microfluidic chip channels and other suitable geometries.

In a microfluidic chip, interaction of a fluid with the channels in the chip can induce a certain amount of dispersion. The main mechanism for this effect is the no slip boundary condition at the walls of the microfluidic channels For a given encoded voxel element of volume V₀ and length L₀, the spreading of the fluid due to Taylor dispersion can be estimated. Because the Peclet number in the direction of the motion is much greater than 1, diffusion along this dimension can effectively be ignored. The ratio of the dispersion length to an initial voxel length is given by:

$$\frac{{L}_{D}}{{L}_{0}} = {[ \frac{1}{105} \frac{t}{D} \frac{{Q}^{2}}{{V}_{0}^{2}} {d}^{2} f ( \frac{d}{W} ) ]}^{1 / 2}$$

where t is effectively the time-of-flight (TOF) and Q is the flow rate. The function, f depends on the exact geometry of the channel. For d=150 um and W=225 um, f≈3. The volume of one voxel is given by V₀≈2.4×10⁻⁵ cm³. This means that to a rough approximation the dispersion ratio is 5 for a time-of-flight of 1 ms, calculated for pure water.

The result of this calculation means that considerable time partitioning could advantageously be used to get accurate localization of a single voxel at this spatial resolution (a time resolution of roughly 40 μs). In some embodiments, this resolution of time partitioning is avoided by using mechanical methods to decrease dispersion. In one embodiment, microfluidic chips having plugged flow are used. In another embodiment, the cross sectional shape of the channel is profiled. In still another embodiment, a polymeric stationary phase anchored to the wall of the microchannel is used to create slip boundary conditions and, hence, minimize dispersion. Alternatively, it is possible to drive the flow by electro-osmosis which gives nearly uniform velocity profiles.

In some embodiments, additional information besides the location of spin density can be encoded during application of the y, z magnetic field gradients. For example, the gradients may be switched in such a manner as to phase encode the velocity of the spins (so called q-encoding) by nulling the moments of the expansion of the time-dependent position that do not correspond to velocity. Other switching gradients may be used to encode acceleration. Velocity encoding techniques are known to those of skill in the art. For example, suitable techniques are described in P. T. Callaghan, Principles of Nuclear Magnetic Resonance Microscopy (Oxford University Press, New York, 1992) and A. Caprihan and E. Fukushima, “Flow measurements by NMR,” Phys. Rep. 198, 195 (1990), both of which are incorporated herein by reference in their entirety.

When combined with the techniques described above, velocity encoding can be used to generate two-dimensional images that indicate the velocity distribution of spins arriving at the detector at a specified time of flight. In this case, the positions of spins within the detector correspond to different velocities. This information allows the partitioning of velocity distribution instead of the typical averaging of velocity within a given voxel as provided by traditional velocity encoding. One unique application of this technique is to characterize the flow of a fluid through porous material. The velocity of fluid flowing through porous material may be different depending on the path the fluid takes through the material. For example, fluid flowing through a given voxel in porous material may flow through different paths with different rates. The technique described above allows the partitioning of the velocity distribution within the voxel, thereby differentiating the various fluid paths through the voxel.

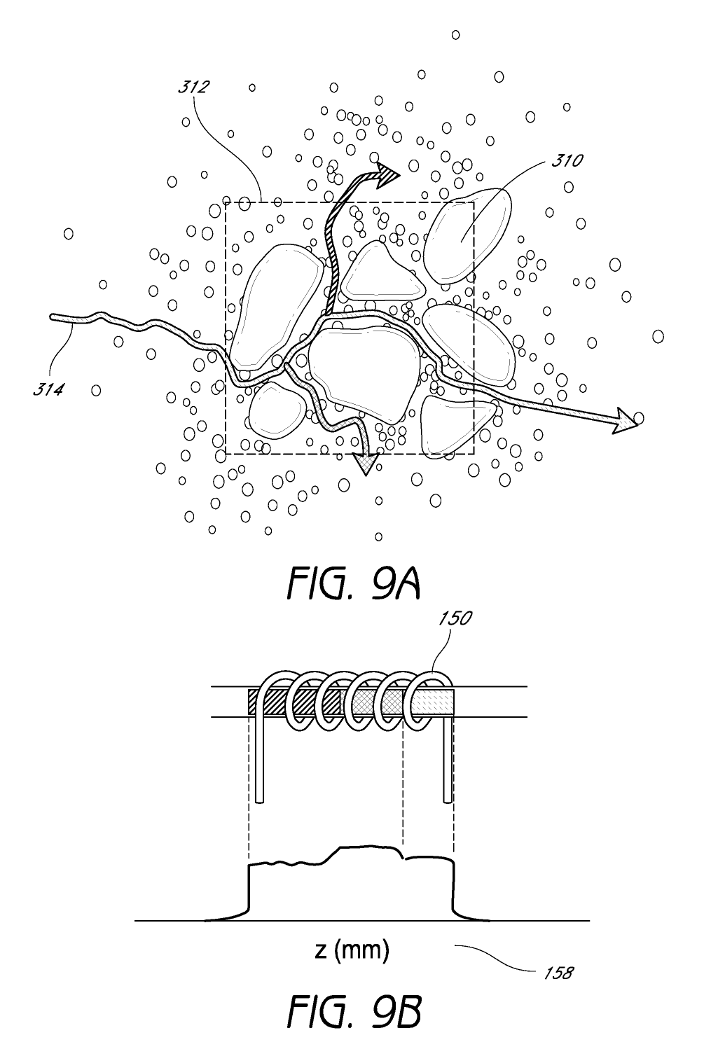

FIG. 9A is a schematic illustrating fluid flow through a porous material 310 within a given voxel 312. Fluid 314 taking different paths through the material 310 may have different velocities, and therefore arrive at the detector at different times. FIG. 9B is a schematic of the detector 150 showing how spins having differing velocities within the voxel 312 become distributed in space within the detector 150. The partitioning of the one-dimensional image 158 obtained with the detector 150 allows partitioning of velocity. Ultimately, following the procedures described above, two-dimensional images of velocity distribution for a given time of flight can be obtained. Information regarding the order of arrival of the various velocities can also be obtained.

Some embodiments include an apparatus for conducting the above-described ultrafast magnetic resonance methods. In some embodiments, such an apparatus includes a plurality of coils for generating magnetic field gradients (e.g., a Maxwell coil pair and a plurality of saddle coils as described above). Some embodiments include driver electronics and control hardware for energizing the coils and generating the magnetic field gradients. Such hardware is well known to those of skill in the art. Some embodiments include a detection coil positioned within the magnetic field gradient coils. In some embodiments, driver electronics and control hardware are provided for driving the detection coil to generate radiofrequency pulses and for using the detection coil to detect free induction decay of a sample within the coil.

In some embodiments, the magnetic field gradient coils and detection coil is provided together in an assembly wherein the detection coil is held in a fixed relationship to the magnetic field gradient coils. In some embodiments, the entire assembly is configured to fit within the bore of the magnet of a conventional NMR or MRI machine. In some embodiments, the assembly further includes a holder within the magnetic field coils configured to hold a flow-through system such as a microfluidic chip. In some embodiments, the holder is designed to hold commercially available microfluidic chips.

In some embodiments, a tube such as a capillary is provided within the detection coil. In some embodiments, the tube comprises a connector for connecting to a flow-through system such as a microfluidic chip. Further embodiments include valves and pumps sufficient to draw fluid through the flow-through system and into the tube.

### EXAMPLE

### Example 1

### Spin Density Imaging

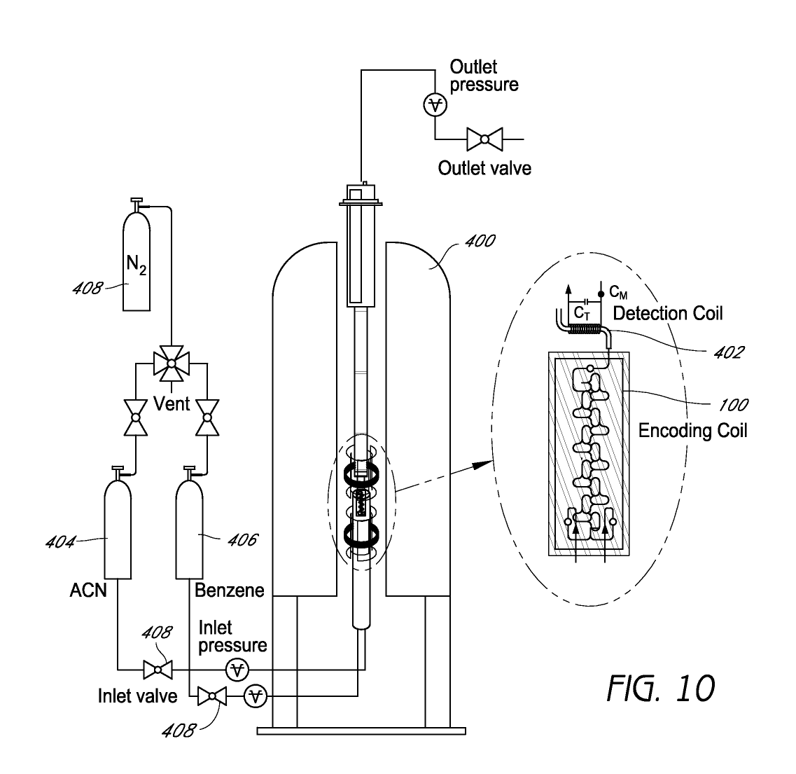

A two-component mixing microfluidic chip having 100 μM channels was dynamically imaged to monitor the flow and mixing of acetonitrile (ACN) and benzene in the channels of the chip. The apparatus is depicted in FIG. 10. The microfluidic chip 100 was placed within the magnet of a commercial 7.0 T NMR spectrometer 400. A commercial imaging probe (Varian Inc.) was affixed in the usual position below the shim stack and gradient coils such that the center of the z gradient coil was aligned with the most homogeneous region of the magnetic field—the so-called ‘sweet spot’. A homebuilt detection probe was positioned from above the magnet such that its microcoil 402 was as close as possible to the sweet spot of the magnet. The two RF coils were shielded from each other by a custom built copper hat which also allowed the tubing to pass through.

The microcoil 402 was constructed out of 99.9% Cu wire with a polyimide coating wound around a 1 mm capillary. The capillary was then removed to allow insertion of PEEK tubing (Upchurch Scientific) with a 360 um OD and 150 um ID. Variable capacitors (Johanson) and chip capacitors (Voltronics corporation) completed the RF resonance circuit. Because no susceptibility matching fluid was used, it was necessary to use a fairly large microcoil compared to what is routinely used for microcoil NMR. Moving to a smaller diameter would provide a significantly higher filling factor and increase sensitivity, at the cost of poorer spectral resolution. With the use of susceptibility matched wire or susceptibility matching fluid (e.g. FC-43) it is possible to increase the sensitivity over the current design to detect concentrations in the low millimolar range.

Pure ACN 404 and benzene 406 solvents were pressurized with nitrogen gas 408 at 50 psi and housed in stainless steel cylinders and supplied to the two input ports of the microfluidic chip. ACN and benzene mix within the wells of the chip. The flow rate of each fluid was controlled by microvalves 408 (Upchurch Scientific, Oak Harbor, Wash.) prior to inserting into the 7.0 T magnet 400.

The pulse sequence used was as described above with respect to FIGS. 4 and 5. Each probe was connected to its own RF amplifier with the detection probe connected to the transmit/receive channel of the spectrometer (Varian, Inova). The encoding coil was controlled by the decoupler channel which allowed for high precision pulse shaping. The initial excitation pulse on the encoding channel consisted of either a hard pulse to excite all the spins on the chip or a spatially selective pulse, typically a sinc in the presence of a pulsed gradient. After initial excitation with a 90 degree pulse the spins evolved under the presence of gradients along y and z which lay parallel to the face of the chip. To save time, the spatial resolution was set to 15×61 (30×122 after zero-filling). The encoding time was less than 200 μs, which was mainly limited by the relatively long 90-time of the initial excitation pulse and not the gradient encoding time. The gradient strengths used never exceeded 10 G/cm. After evolution, the magnetization was stored along the longitudinal axis by the application of a hard pulse which acted on all the spins in the sample. The phase of this pulse was arrayed in steps of 90 degrees for phase cycling. This phase was set to match that of the receiver phase.

The magnetization, having been stored along the longitudinal direction, now flowed to the detector where it was read out by a series of hard, 90 degree pulses. In order to obtain imaging information, the magnetization was allowed to precess for 50 μs in the presence of a gradient now directed along the coil axis (set to the x direction). The remainder of the time prior to the next excitation pulse was spent undergoing chemical shift evolution in which spectral information was retrieved. Because no reaction is assumed to take place in the detector one can correlate the imaging information with the chemical shift information in the detector only. The residence time was measured by an inversion recovery experiment to be about 20 ms, which was enough time to separate resonance that are more than 50 Hz apart—more than sufficient to clearly distinguish the single ACN and benzene resonances. The 20 ms resolution of the one-dimensional detector images was subdivided into 11 points, giving a time resolution of less than 2 ms. Because of the very high sensitivity in the detection coil, this could have easily been extended to 100 pts or more; however, for the phase encoding scheme, which is done point-by-point, this would have made the experiment time considerably long.

The total experiment time for the pure phase encoding scheme was given by the total flow time through the chip multiplied by the number of indirect points multiplied by the number of phase cycles. The flow time through the chip was approximately 1.0 s and the number of points was given by the resolution along all three gradient axes (15×61×11=10065). This resulted in an approximately 11 hr acquisition time.

The experiment was also performed using spectrally selective pulses which excited each resonance in the detector followed by spin echo frequency encoding. For the frequency encoding scheme, the experiment time was reduced by a factor of 11 since no phase encoding was necessary in the detection coil. However, a different experiment had to be run for each fluid species, reducing the gain by a factor of 2. The total experiment time for this scheme was approximately 2 hours. The fast flow rate, however, makes this less robust and provides poorer SNR.

The number of partial images (i.e., each time-of-flight image) obtained with the pure phase encoding scheme was given by the number of detection pulses times the number of points taken in the detection coil dimension. 1100 partial images were obtained or 2200 with zero filling. Therefore, while the total acquisition was long, each partial image only took 36 s (18 s with zero filling). This is in contrast to the 10 hrs needed to obtain a single image (albeit at slightly higher spatial resolution) obtained by directly imaging the chip 100 under stopped flow conditions.

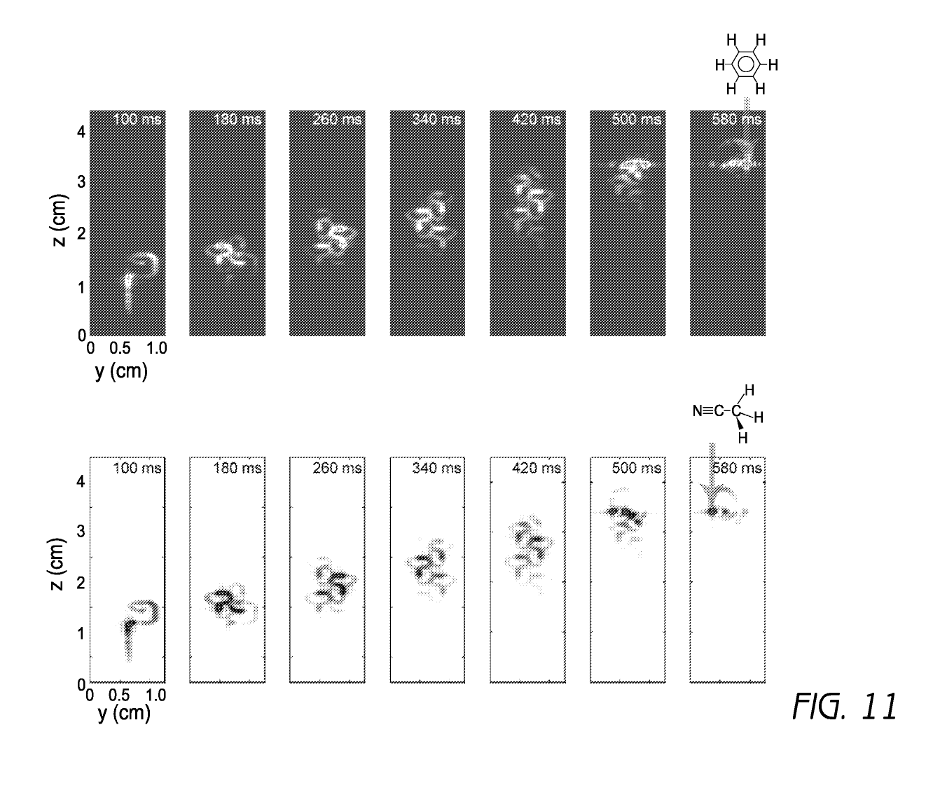

FIG. 11 shows the results of the remotely detected phase encoded experiment. Each panel represents the spatial locations of spins that took a given amount of time to reach the detector (i.e. a given time-of-flight (TOF) from the excitation pulse). The dark panels illustrate the time-of-flight images for the benzene and the light panels illustrate the time-of-flight images for the ACN. The progression through the chip is easily seen with the last panels corresponding to the inlet where each fluid species enters. Mixing occurs around a TOF of 500 ms, after which (<500 ms TOF) the images of each species looks very similar. The mixing time was therefore less than 80 ms. ACN and benzene were separated by their chemical shifts in the detection region. The resolution in the 1 mm coil is very high relative to the encoding region where susceptibility broadening nearly destroys the entire signal. Even though the volume in the detection coil is less than 5% of the total volume in the encoding coil, the signal-to-noise is nearly 20 times higher, which makes the mass sensitivity over 400 times higher. In reality the gain in remote detection is less because of T₁ noise which manifests itself in an indirect experiment such as this. That is, because the experiment is repeated many times, fluctuations in the flow over time will manifest itself as noise in the final image. Fortunately, the flow in microfluidic channels is so stable and reproducible over long periods of time that this does not contribute significantly to SNR loss. Signal gain is estimated at over 100.

Because there is no visual aid to monitor the flow of the fluids, the NMR signal itself was used to make sure both species were exiting the chip in approximately equal proportions. Measuring the flow rate through the detection coil was done by implementing an inversion recovery pulse sequence where spins were inverted prior to excitation by a pi/2 pulse at different time increments. It was confirmed that both species flow through the detection coil at an equal rate and exit the coil in about 20 ms (i.e., the residence time), which was set as the repetition time in the stroboscopic part of the remote sequence. For ultrahigh time resolution experiments, an image was produced for each of these pulses.

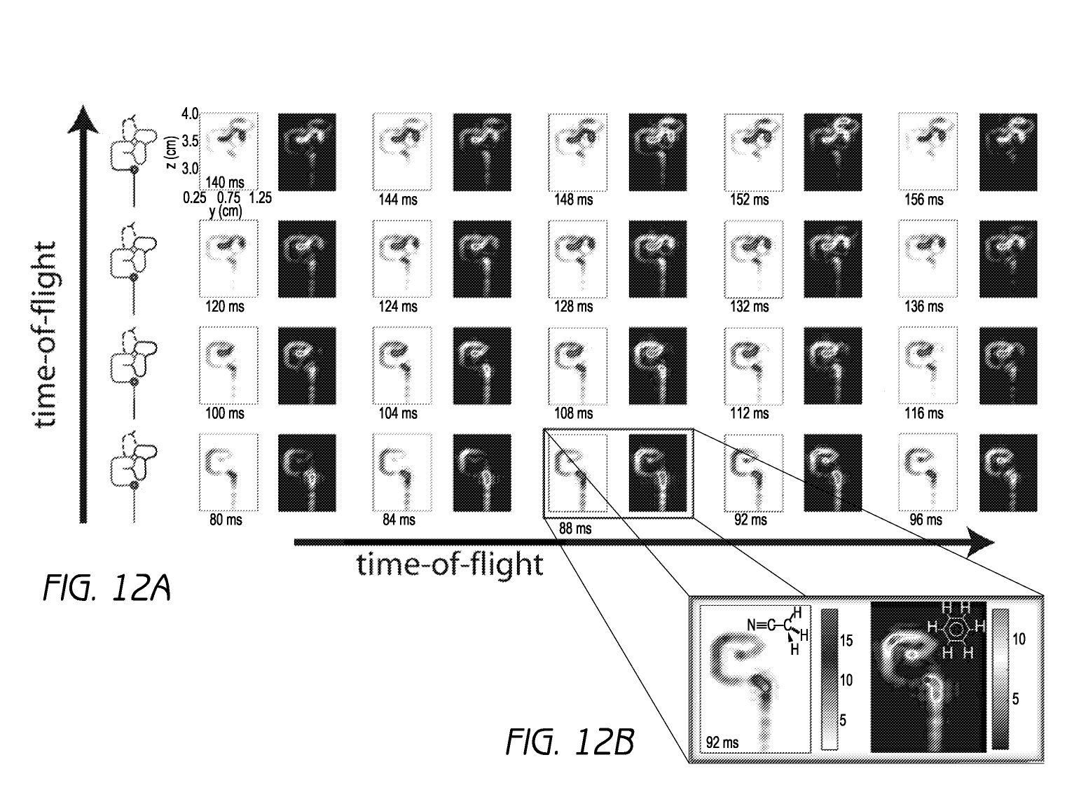

FIGS. 12A-12B shows a small subsection of the images obtained from the full data set. Time-of-flight increases in 4 ms increments starting from the bottom left and moving to the right of each row. The dark panels illustrate the time-of-flight images for the benzene and the light panels illustrate the time-of-flight images for the ACN. Many interesting features of the flow can be seen at the 4 ms timescale displayed that are not apparent without the time slicing. This subsection only shows the outlet region of the chip since the effects of the higher time resolution are more apparent when dispersion is minimized. Due to the geometry of the chip, there is significant dispersion created by the 3D mixing channels which act to stretch the fluid for improved mixing. Therefore, at the outlet, the dispersion is at a minimum since it is closest to the detection coil. The similarity of the images of the ACN and benzene shows that the fluids are fairly well mixed at this point; however subtle differences still appear. For example, while the flow in the channels appears nearly identical indicating good mixing, the TOF patterns appear slightly differently at the outlet connector that couples the chip to the external tubing. This result indicates that the fluids may begin to separate in this region. More quantitative information can be seen from examining the dispersion curves for voxels in the connector region for each chemical species.

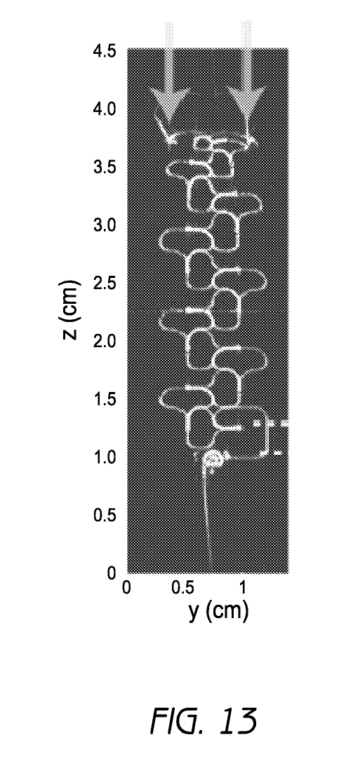

For comparison purposes, a high-resolution direct image of the microfluidic chip 100 was obtained. The resulting image is depicted in FIG. 13. The fluid was stationary during the image acquisition since it was found that no image was obtainable under flow. A spin-echo sequence which refocuses inhomogeneities required a 10 hour scan time for 256×256 points. While faster sequences are available they require significantly more sensitivity than is available in the small channels of the chip. The entire void space volume of the chip, excluding the inlet and outlet tubing, was below 4 uL. Each fluid component was therefore less than 2 mL. The sensing coil volume was roughly 30 cm³, which means that the filling factor was less than 1/10,000 for each component. This large coil was necessary to encompass the macroscopic chip which is about 2 cm×4 cm×3 mm and, for practical purposes, the chip holder which keeps things properly positioned. Furthermore, susceptibility broadening due to the chip materials made any signal from the chip difficult to see even with an adiabatic excitation designed to cover a large bandwidth. Finally, the flow velocity inside the chip reached a maximum of more than 50 cm/s, making refocusing, which is necessary in fast imaging sequences (e.g. EPI), nearly impossible because of relatively long gradient rise and fall times.

### Example 2

### Velocity Imaging

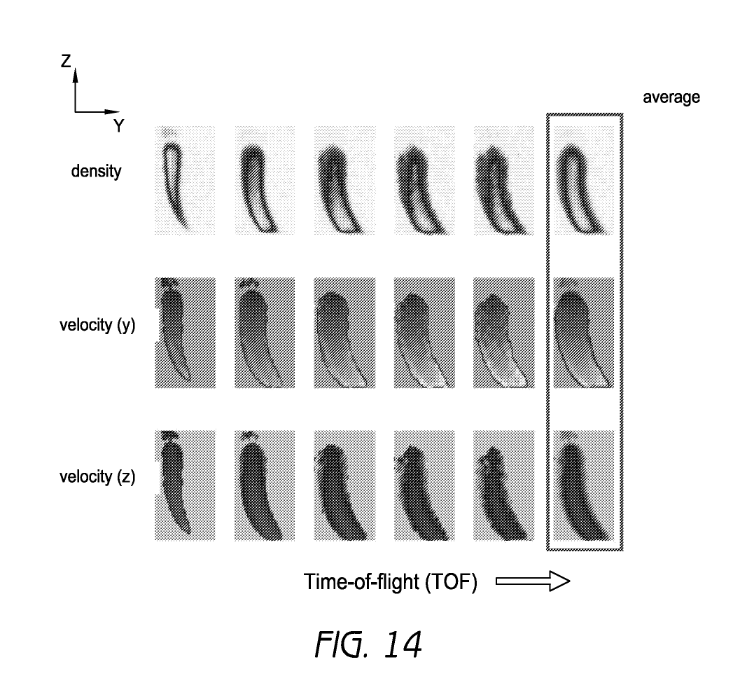

Fluid flowing through a 150 μm diameter capillary was velocity encoded using a q-encoding gradient switching technique and detected using the remote-detection time-of-flight technique described herein. FIG. 14 depicts a series of partial images obtained when encoding to obtain spin density (first row of images), the y-component of velocity (second row of images), and the z-component of velocity (third row of images). As above, each successive partial image corresponds to successive times of flight. Each successive image represents a 20 ms increase in time-of-flight. The last image of each row depicts the spin density or velocity distribution averaged over all partial images depicted. The velocity component images indicate the distribution of velocities with the brighter shading representing faster velocities.

The successive velocity distribution images indicate the order in which the various velocities arrive at the detector. In other words, the velocities depicted in the first image correspond to those that arrived at the detector first. The no-slip condition of the fluid flow (due to laminar flow) can be seen in the z-component images near the walls of the capillary (i.e., the velocities are lower near the capillary walls).

Although the invention has been described with reference to embodiments and examples, it should be understood that numerous and various modifications can be made without departing from the spirit of the invention. Accordingly, the invention is limited only by the following claims.

What is claimed is:

1. A magnetic resonance detection method, comprising:
a) applying a static magnetic field to a flow-through system comprising a fluid;
b) applying a first radiofrequency pulse to the fluid located within the flow-through system to excite nuclear spins in the fluid;
c) transporting the fluid from the flow-through system into a detection coil; and
d) performing one-dimensional nuclear magnetic resonance imaging of the fluid within the detection coil.

2. The method of claim 1, comprising applying a magnetic field gradient to the flow-through system after application of the first radiofrequency pulse.

3. The method of claim 2, comprising generating an image of fluid within the flow-through system.

4. The method of claim 3, wherein generating the image of fluid within the flow-through system comprises:
repeating steps b) through d) one or more times wherein a different magnetic field gradient is applied to the flow-through system after application of the first radiofrequency pulse;
constructing a k-space or kt-space with data obtained from each repetition;
converting the k-space or kt-space to a representation comprising real space coordinates;
relating position within the detection coil to a time-of-flight of fluid from the flow-through system to the detection coil; and
constructing an image of fluid within the flow-through system corresponding to the time-of-flight.

5. The method of claim 3, wherein separate images of fluid within the flow-through system are obtained for a plurality of chemical species within the fluid.

6. The method of claim 1, comprising applying a second radiofrequency pulse to the fluid located within the flow-through system to store magnetization information along the longitudinal axis of the nuclear spins.

7. The method of claim 1, wherein the first radiofrequency pulse comprises a hard 90 degree pulse to excite all spins within the flow-through system.

8. The method of claim 1, wherein the first radiofrequency pulse comprises a soft radiofrequency pulse and wherein a magnetic field gradient is applied to the flow-through system simultaneously with the first radiofrequency pulse.

9. The method of claim 8, wherein the soft radiofrequency pulse has a sinc waveform.

10. The method of claim 1, wherein the flow-through system comprises a microfluidic chip.

11. The method of claim 1, wherein performing the one-dimensional nuclear magnetic resonance imaging comprises:
d1) applying a third radiofrequency pulse to the fluid within the detection coil using the detection coil;
d2) applying a magnetic field gradient to the fluid within the detection coil; and
d3) detecting free induction decay with the detection coil.

12. The method of claim 11, wherein the third radiofrequency pulse comprises a hard 90 degree pulse to excite all spins within the detection coil.

13. The method of claim 11, wherein the third radiofrequency pulse comprises a spectrally selective pulse.

14. The method of claim 11, wherein performing the one-dimensional nuclear magnetic resonance imaging comprises using phase encoding by repeating steps b), c), d1), d2), and d3) with a different magnetic field gradient being applied to the fluid within the detection coil.

15. The method of claim 1, comprising obtaining a nuclear magnetic resonance spectrum of the fluid.

16. The method of claim 15, wherein the nuclear magnetic resonance spectrum is obtained for fluid within a sub-volume of the detector coil.

17. The method of claim 16, wherein obtaining the nuclear magnetic resonance spectrum comprises:
repeating steps b) through d) one or more times wherein a different magnetic field gradient is applied to the flow-through system for each repetition after application of the first radiofrequency pulse;
constructing a kt-space with data obtained from each repetition;
converting the kt-space to a representation comprising real space coordinates and a frequency coordinate;
relating position within the detection coil to a time-of-flight of fluid from the flow-through system to the detection coil; and
selecting an NMR spectrum from the converted kt-space representation corresponding to the time-of-flight and a desired location of fluid within flow-through system.

18. A method of imaging fluid within a microfluidic chip, the method comprising:
a) applying a first radiofrequency excitation pulse and a magnetic field gradient to fluid within the chip;
b) allowing the fluid to flow through a detection coil located remotely from the chip;
c) applying a second radiofrequency excitation pulse with the detection coil to the fluid within the detection coil;
d) applying a magnetic field gradient to the fluid within the detection coil;
e) measuring a free induction decay curve with the detection coil;
f) repeating steps c) through e) until all fluid within the chip at the time of the application of the first excitation pulse has flowed through the detector;
g) repeating steps a) through f) for a variety of magnetic field gradients applied to the chip and a variety of magnetic field gradients applied to the fluid within the detection coil;
h) constructing a kt-space from the plurality of free induction decay curves; and
i) converting the kt-space to a real image of spin density within the microfluidic chip for desired time-of-flight of the fluid flowing from the chip to the detector.

19. The method of claim 18, wherein separate real images are constructed corresponding to a plurality of times-of-flight of the fluid flowing from the chip to the detector.

20. The method of claim 18, wherein separate real images are constructed for a plurality of chemical species within the fluid.

21. The method of claim 18, wherein the microfluidic chip comprises immobilized chemical or biological agents that interact with a chemical species within the fluid.

22. The method of claim 21, wherein the interaction slows the time-of-flight through the chip to the detection coil.

23. The method of claim 22, wherein a time-of-flight of the chemical species through the immobilized chemical or biological agents is determined from one or more images obtained in step i).

24. The method of claim 23, wherein the identity of the chemical species is determined based on the determined time-of-flight.

25. An ultrafast nuclear magnetic resonance apparatus, comprising:
a plurality of coils and corresponding drivers configured to apply magnetic field gradients in three dimensions; and
a detection coil and corresponding driver configured to apply radiofrequency excitation pulses and detect nuclear resonance free induction decay, wherein the detection coil is positioned within the plurality of gradient generating coils such that magnetic field gradients can be generated within the detection coil.

26. The apparatus of claim 25, comprising a holder located within the plurality of gradient generating coils configured to hold a flow-through device.

27. The apparatus of claim 26, wherein the flow-through device is a microfluidic chip.

28. The apparatus of claim 25, comprising a tube positioned within the detection coil, wherein the tube comprises a connector configured to connect to a flow-through device.

29. The apparatus of claim 28, wherein the flow-through device is a microfluidic chip.

30. The apparatus of claim 25, comprising a microfluidic chip positioned within the plurality of gradient generating coils and a tube connected to an output of the microfluidic chip and positioned within the detection coil.

31. The apparatus of claim 25, wherein the apparatus is configured to fit within an NMR spectrometer.
